(19) United States
(12) Patent Application Publication
(10) Pub. No.: US 2023/0235771 A1
(43) Pub. Date: Jul. 27, 2023

(54) FASTENING DEVICE

(71) Applicant: FIVETECH TECHNOLOGY INC., New Taipei City (TW)

(72) Inventors: TING-JUI WANG, New Taipei City (TW); YING-TE YU, New Taipei City (TW)

(21) Appl. No.: 18/088,805

(22) Filed: Dec. 27, 2022

(30) Foreign Application Priority Data
Jan. 27, 2022 (TW) 111103753

(51) Int. Cl. F16B 21/02; H05K 7/20

(52) U.S. Cl. CPC F16B 21/02; H05K 7/2049

(57) ABSTRACT

A fastening device is introduced. The fastening device includes a seat body, a first fastening body and a second fastening body. The seat body may be disposed on a first object; the first fastening body is movably provided in the seat body, the first fastening body cooperates with the seat body for fastening and unfastening, so that the first fastening body couples with or separates from a second object; the second fastening body is movably provided in the first fastening body, the second fastening body cooperates with the first fastening body for fastening and unfastening, so that the second fastening body couples with or separates from a third object.

### CROSS-REFERENCE TO RELATED APPLICATION

This non-provisional application claims priority under 35 U.S.C. § 119(a) on Patent Application No(s). 111103753 filed in Taiwan, R.O.C. on Jan. 27, 2022, the entire contents of which are hereby incorporated by reference.

### BACKGROUND OF THE INVENTION

### 1. Field of the Invention

The present disclosure relates to a fastening device, and in particular to a fastening device which can be used to couple together and separate at least two objects repeatedly and quickly.

### 2. Description of the Related Art

Generally, when coupling together at least one object, it is usually achieved by locking with screws to couple the object.

In terms of the above-mentioned customary fixing method, although at least one object can be fixed and coupled together in a manner that is not easy to separate, in addition to causing a situation that is not easy to assemble, at least one object will be difficult to disassemble because of the fixing and coupling method of the screws.

### BRIEF SUMMARY OF THE INVENTION

In view of the above disadvantages of the prior art, the inventor developed a fastening device, with a view to achieving the purpose of coupling together and separating repeatedly and quickly.

To achieve the above objective and other objectives, the present disclosure provides a fastening device, comprising a seat body, a first fastening body and a second fastening body. The seat body may be disposed on a first object; the first fastening body is movably provided in the seat body, the first fastening body cooperates with the seat body for fastening and unfastening, so that the first fastening body laterally moves to couple with or separate from a second object; the second fastening body is movably provided in the first fastening body, the second fastening body cooperates with the first fastening body for fastening and unfastening, so that the second fastening body rotationally moves to couple with or separate from a third object.

The present disclosure provides a fastening device, comprising a seat body, a first fastening body and a second fastening body. The seat body may be disposed on a first object; the first fastening body is movably provided in the seat body, so that the first fastening body moves to couple with or separate from a second object; the second fastening body is movably provided in the first fastening body, so that the second fastening body moves to couple with or separate from a third object.

The present disclosure provides a fastening device, comprising a seat body and a second fastening body. The seat body may be provided on a first object; the second fastening body is movably provided in the seat body, so that the second fastening body rotationally moves to couple with or separate from a third object.

In the fastening device, the seat body has at least one assembling part, the assembling part may be provided for the seat body to be disposed on the first object.

In the fastening device, the assembling part is disposed on the first object by fastening, soldering, locking, expanding connection, straight fastening, rotary fastening or adhesion.

In the fastening device, the seat body has at least one assembling part or at least one elastic fastening part, or the assembling part may be provided for the seat body to be disposed on the first object, or the elastic fastening parts abut against the first object.

In the fastening device, the seat body has an accommodating area, the first fastening body is movably provided in the accommodating area.

In the fastening device, the first fastening body or the seat body is provided with a sliding part, the sliding part is disposed in the seat body or the first fastening body with a bolt part, so that the first fastening body is movably provided in the seat body.

In the fastening device, the seat body has a first setting part, the first fastening body has a first fixing part, the first setting part corresponds to the first fixing part, so that the first fixing part cooperates with the first setting part for fastening and unfastening to couple with or separate from the second object.

In the fastening device, the first fixing part has a first limiting flange, the second object has a recess part, the recess part of the second object is fitted into the first limiting flange.

In the fastening device, the first fastening body has an operating part, the operating part may control the first fastening body to move on the seat body.

In the fastening device, the first fastening body and the seat body therebetween have a first elastic element, one end of the first elastic element abuts against the seat body, the other end of the first elastic element abuts against the first fastening body, the first elastic element can make the first fastening body normally located in a locking position or normally located in an unlocking position.

In the fastening device, the first fastening body and the seat body therebetween have a first elastic element, the first fastening body has a blocking part, one end of the first elastic element abuts against the seat body, the other end of the first elastic element abuts against the blocking part, and the first elastic element can make the first fastening body normally located in a locking position or normally located in an unlocking position.

In the fastening device, the second fastening body is movably provided in the first fastening body with a shaft part.

In the fastening device, the shaft part is pressured by external force to combine the first fastening body by expanding connection.

In the fastening device, the second fastening body has a positioning part, the first fastening body has a first restriction part and a second restriction part, when the positioning part is combined in the first restriction part, the second fastening body is located in an unfastening position, when the positioning part is combined in the second restriction part, the second fastening body is located in a fastening position.

In the fastening device, the second fastening body has a positioning part, the first fastening body has a first restriction part or a second restriction part, when the positioning part is combined in the first restriction part, the second fastening body is located in an unfastening position or fastening position, or when the positioning part is combined in the second restriction part, the second fastening body is located in a fastening position or unfastening position.

In the fastening device, one end of the second fastening body has a second fixing part, the other end of the second fastening body has a give-way part, the second fastening body is rotated after the third body passes through the give-way part, so that the second fixing part couples with the third object.

In the fastening device, one end of the second fastening body has a second fixing part, the other end of the second fastening body has a give-way part, the first fastening body has a second setting part, the third object is disposed on the second setting part after passing through the give-way part, and then the second fastening body is rotated, so that the second fixing part couples with the third object.

In the fastening device, the second setting part has a second limiting flange, the third object has a recess part, the recess part of the third object is fitted into the second limiting flange.

In the fastening device, one end of the second fastening body has a second fixing part, the first fastening body has a second setting part, the third object is disposed on the second setting part, and then the second fastening body is rotated, so that the second fixing part couples with the third object.

In the fastening device, the second fastening body is movably provided in the first fastening body with a shaft part, the shaft part is provided with a second elastic element, one end of the second elastic element abuts against the first fastening body, the other end of the second elastic element abuts against one end of the shaft part, the second elastic element can make the second fastening body normally located at a top of the first fastening body.

In the fastening device, the second fastening body is movably provided in the first fastening body with a shaft part, the shaft part is provided with a second elastic element, one end of the second elastic element abuts against the first fastening body, the other end of the second elastic element abuts against one end of the shaft part.

In the fastening device, the second fastening body is movably provided in the first fastening body with a shaft part, the shaft part is provided with a second elastic element, one end of the second elastic element abuts against the first fastening body, the other end of the second elastic element abuts against one end of the shaft part, the second elastic element may enable the second fastening body to apply a coupling force of normal elastic downward pressure to press against the third object.

In the fastening device, the second fastening body is used to apply a coupling force of normal elastic downward pressure to press against the third object.

In the fastening device, the second object or the third object is a printed circuit board, PCB board, computer carrier board, heat dissipating sheet, radiator, memory, M.2 card, metallic piece, hard disk, chip, semiconductor, heating element, heat dissipating element, plastic piece or non-metallic piece.

In the fastening device, the second object is a heating element, the third object is a heat dissipation element, wherein the third object is used to dissipate heat for the second object.

In the fastening device, the third object is a heat dissipation element, used to be pressed down by the spring force on the second object or the chip of the second object for heat dissipation.

In the fastening device, the second fastening body is movably provided in the first fastening body with a shaft part, and has a second elastic element, one end of the second elastic element abuts against the first fastening body, the other end of the second elastic element abuts against the second fastening body, the second elastic element can make the second fastening body normally located at a top of the first fastening body.

In the fastening device, the second fastening body is movably provided in the first fastening body with a shaft part, and has a second elastic element, one end of the second elastic element abuts against the first fastening body, the other end of the second elastic element abuts against the second fastening body.

In the fastening device, the second fastening body is movably provided in the first fastening body with a shaft part, and has a second elastic element, one end of the second elastic element abuts against the first fastening body, the other end of the second elastic element abuts against the second fastening body, the second elastic element may enable the second fastening body to apply a coupling force of normal elastic downward pressure to press against the third object.

In the fastening device, the second fastening body is pushed and abutted by the second elastic element for rotationally elastic movement.

In the fastening device, the second fastening body has a fixing part, the third object has a corresponding fixing part, the fixing part and the corresponding fixing part are engaged with each other for fixing or anti-rotation or abutting against or fastening or applying pressure or pressing downward.

Therefore, the fastening device according to the present disclosure can make the seat body combined with the first object, and the first fastening body and the second fastening body respectively lock on the second object and the third object, or unlock on the second object and the third object, so as to couple together and separate at least two objects, and achieve the purpose of coupling together and separating repeatedly and quickly.

### BRIEF DESCRIPTION OF THE DRAWINGS

FIG. 1 is a schematic outside view of a fastening device of the present disclosure.

FIG. 2 is a schematic exploded view of the fastening device of the present disclosure.

FIG. 3 is another schematic exploded view of the fastening device of the present disclosure.

FIG. 4 is a schematic view of a sectional state of the fastening device of the present disclosure.

FIG. 5 is a schematic view 1 of a state of use of the fastening device of the present disclosure.

FIG. 6 is a schematic view 2 of the state of use of the fastening device of the present disclosure.

FIG. 7 is a schematic view 3 of the state of use of the fastening device of the present disclosure.

FIG. 8 is a schematic view 4 of the state of use of the fastening device of the present disclosure.

FIG. 9 is a schematic view 5 of the state of use of the fastening device of the present disclosure.

FIG. 10 is a schematic view 6 of the state of use of the fastening device of the present disclosure.

FIG. 11 is a schematic view 7 of the state of use of the fastening device of the present disclosure.

FIG. 12 is a schematic view 8 of the state of use of the fastening device of the present disclosure.

FIG. 13 is a schematic view 9 of the state of use of the fastening device of the present disclosure.

FIG. 14 is a schematic view 10 of the state of use of the fastening device of the present disclosure.

FIG. 15 is a schematic view 11 of the state of use of the fastening device of the present disclosure.

FIG. 16 is a schematic view 1 of a state of use of the fastening device of another embodiment of the present disclosure.

FIG. 17 is a schematic view 2 of the state of use of the fastening device of another embodiment of the present disclosure.

FIG. 18 is a schematic view 3 of the state of use of the fastening device of another embodiment of the present disclosure.

FIG. 19 is a schematic view of a state of use of the fastening device of still another embodiment of the present disclosure.

### DETAILED DESCRIPTION OF THE INVENTION

To facilitate understanding of the object, characteristics and effects of this present disclosure, embodiments together with the attached drawings for the detailed description of the present disclosure are provided.

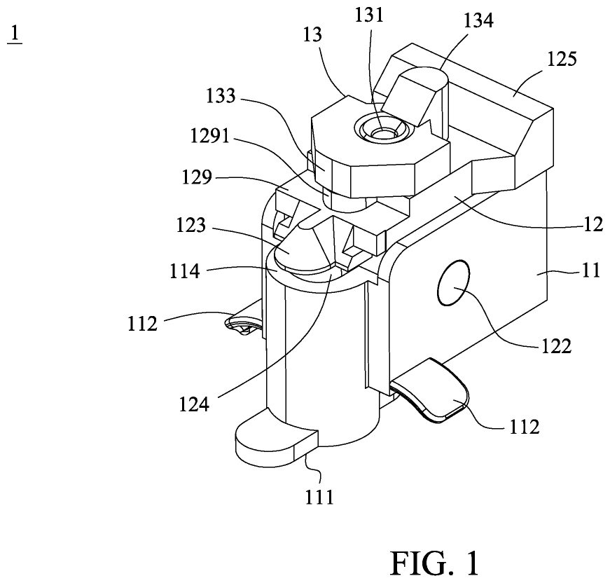

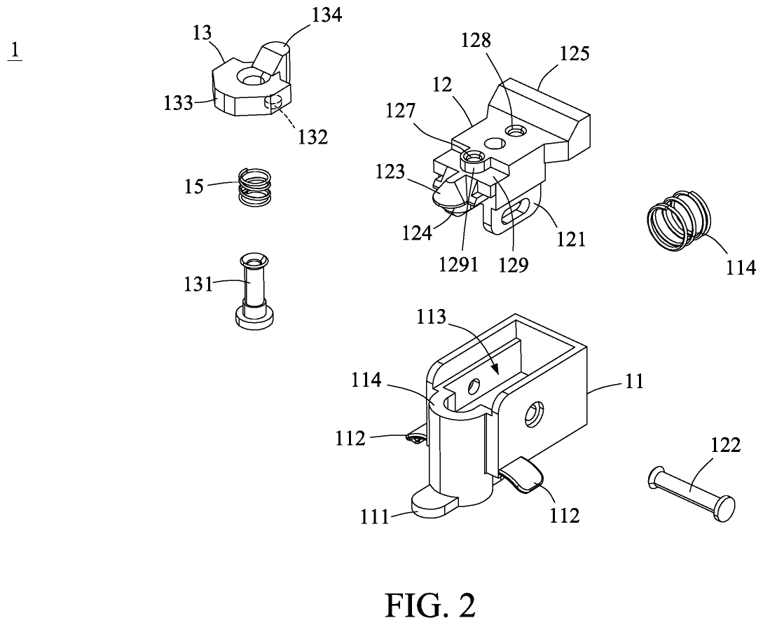

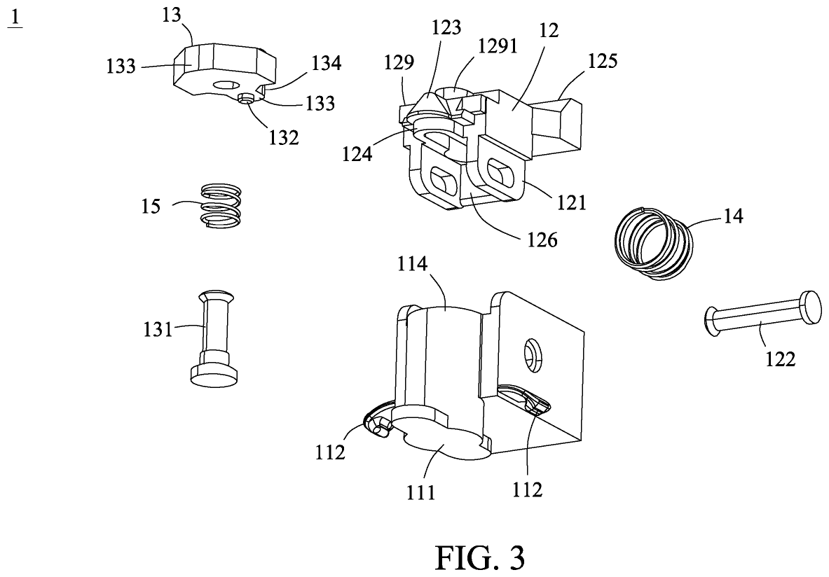

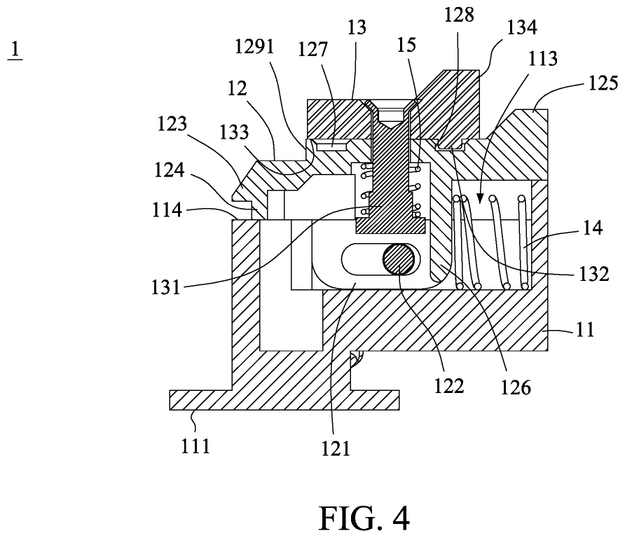

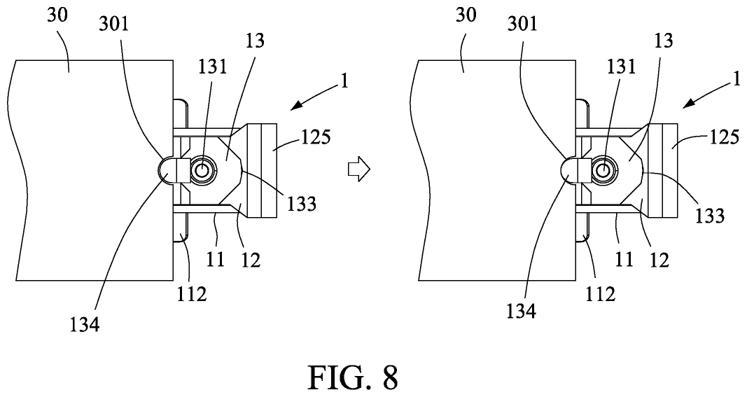

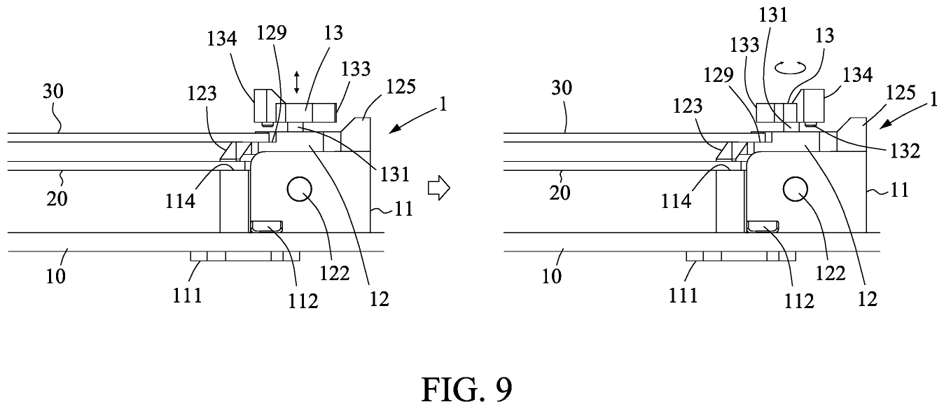

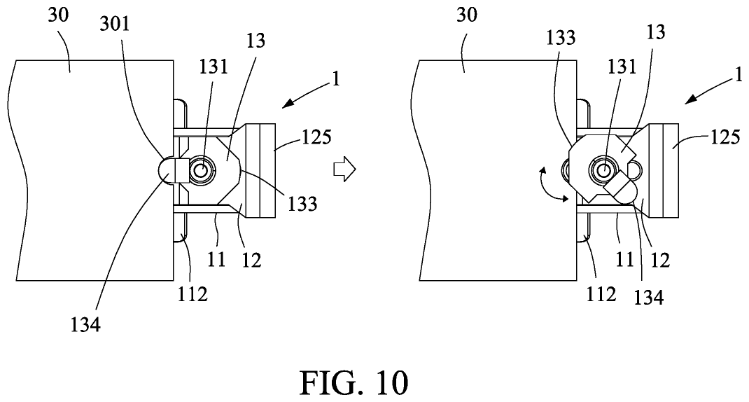

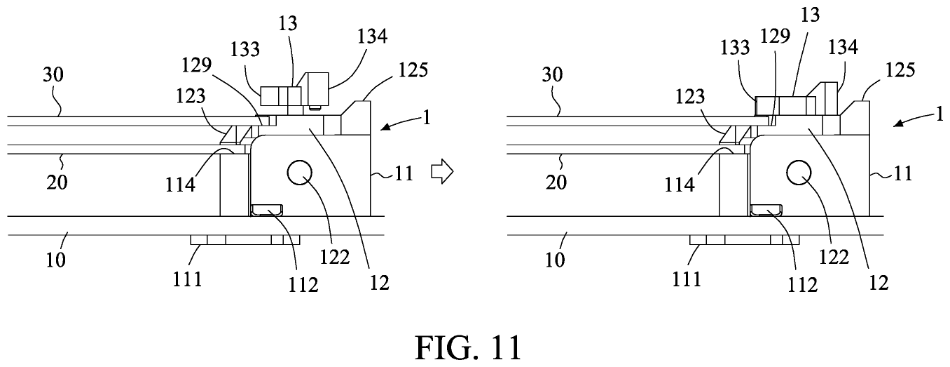

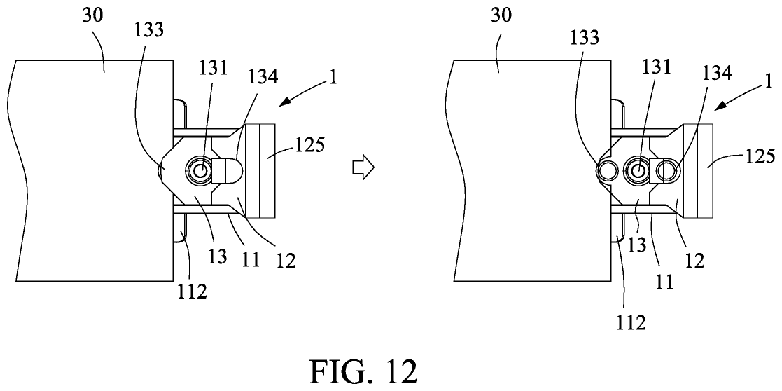

Referring to FIGS. 1 to 15, as shown in the drawings, the present disclosure provides a fastening device 1, which comprises a seat body 11, a first fastening body 12 and a second fastening body 13.

The seat body 11 may be disposed on a first object 10.

The first fastening body 12 is movably provided in the seat body 11, the first fastening body 12 cooperates with the seat body 11 for fastening and unfastening, so that the first fastening body 12 laterally moves to couple with or separate from a second object 20.

The second fastening body 13 is movably provided in the first fastening body 12, the second fastening body 13 cooperates with the first fastening body 12 for fastening and unfastening, so that the second fastening body 13 rotationally moves to couple with or separate from a third object 30.

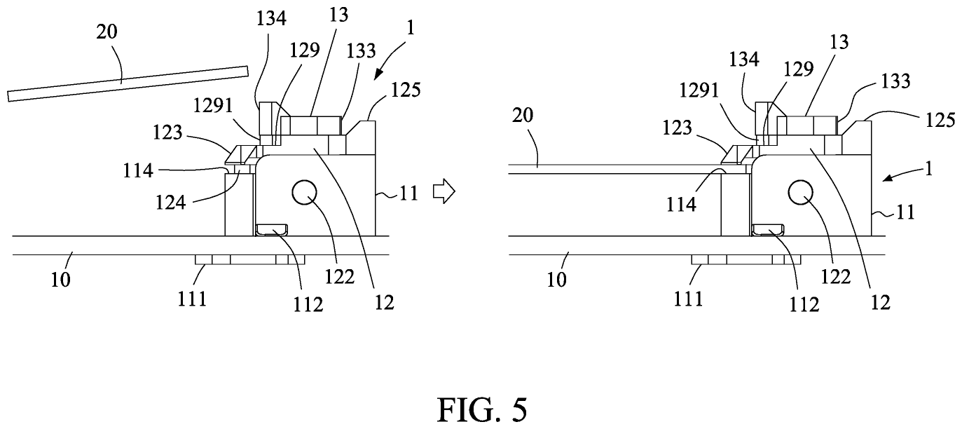

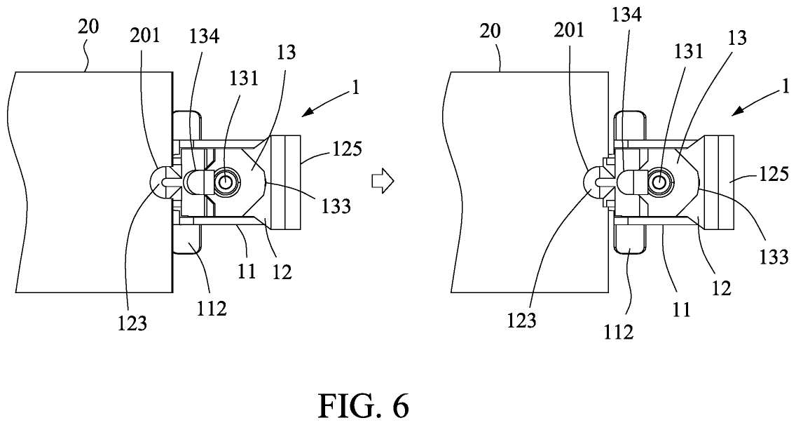

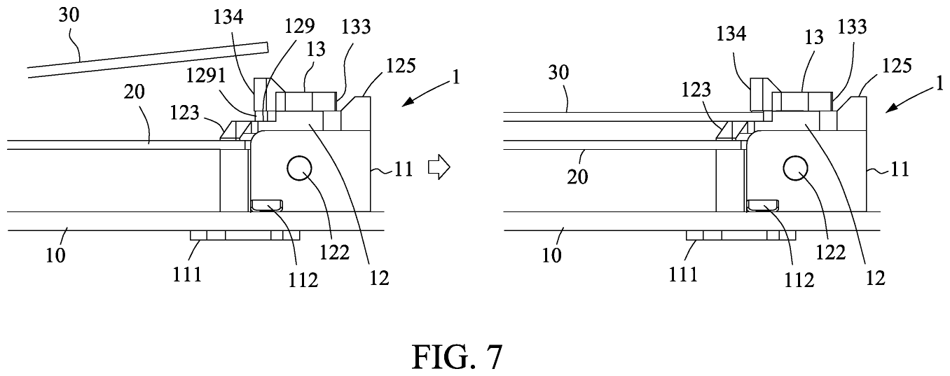

When used, the fastening device 1 may be combined on the first object 10, and then the second object 20 is directly pressed down at one end of the first fastening body 12 to make the first fastening body 12 move laterally, so that a bottom of one end of the first fastening body 12 cooperates with a top of one end of the seat body 11 to fasten to the second object 20, thereby locking the first fastening body 12 on the second object 20, and thus the first fastening body 12 and the second object 20 are coupled together (as shown in FIGS. 5 and 6); the third object 30 is then placed on a surface of one end of the first fastening body 12, and the second fastening body 13 is rotationally moved, so that a bottom of one end of the second fastening body 13 cooperates with a top of one end of the first fastening body 12 to fasten to the third object 30, thereby locking the second fastening body 13 on the third object 30, and thus the second fastening body 13 and the third object 30 are coupled together (as shown in FIGS. 7 to 12).

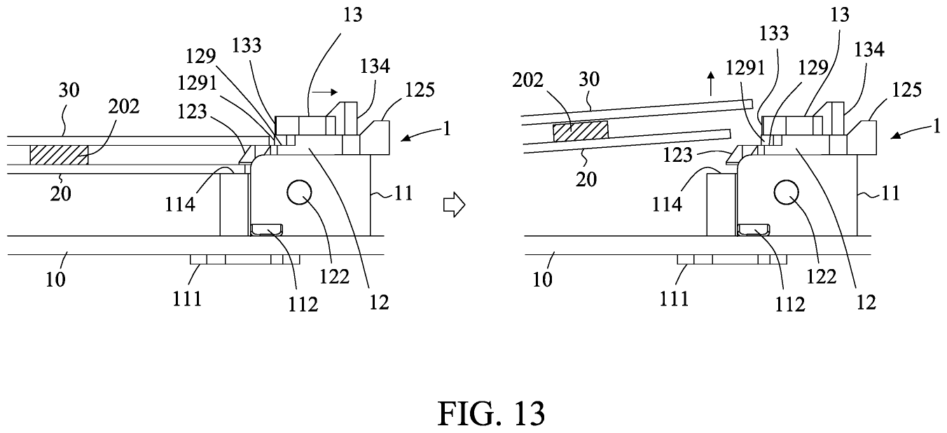

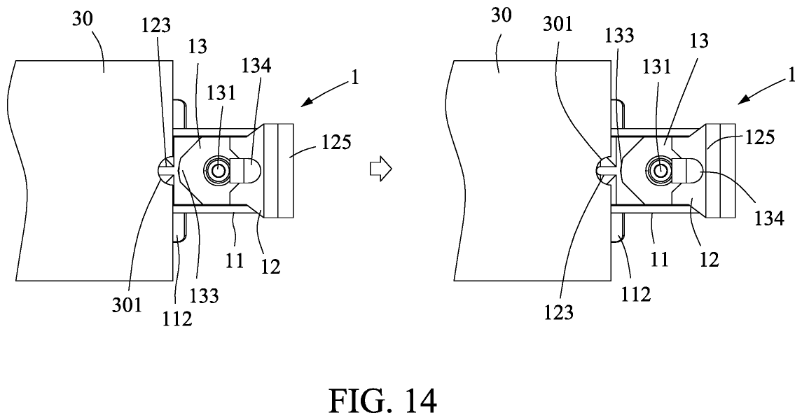

When the second object 20 and the third object 30 are to be separated, the first fastening body 12 moves laterally toward a direction away from the second object 20 and the third object 30, so that the first fastening body 12 links the second fastening body 13, and thus the first fastening body 12 and the second fastening body 13 are simultaneously separated from the second object 20 and the third object 30 (as shown in FIGS. 13 to 14); in addition, the second fastening body 13 may also be rotated, so that the bottom of one end of the second fastening body 13 leaves the third object 30, and then the movement of the first fastening body 12 is performed. Accordingly, the seat body 11 may be combined with the first object 10, and the first fastening body 12 is used to cooperate with the second fastening body 13 to perform fastening and unfastening, so that the first fastening body 12 and the second fastening body 13 are coupled together or separated from the second object 20 and the third object 30, so as to couple together and separate the two objects, and achieve the effect of coupling together and separating repeatedly and quickly.

In one embodiment of the present disclosure, the seat body 11 has at least one assembling part 111, the assembling part 111 is disposed at a bottom of the seat body 11, the assembling part 111 may be provided for the seat body 11 to be disposed on the first object 10 by soldering, fastening, locking, expanding connection, straight fastening, rotary fastening or adhesion, etc. Accordingly, the seat body 11 may be firmly disposed on the first object 10 to facilitate movement operation of the first fastening body 12 and the second fastening body 13.

In one embodiment of the present disclosure, the seat body 11 has at least one assembling part 111 and at least one elastic fastening part 112, the assembling part 111 is disposed at a bottom of the seat body 11, the elastic fastening parts 112 are disposed at two sides of the seat body 11, the assembling part 111 may be provided for the seat body 11 to be disposed on the first object 10, the elastic fastening parts 112 abut against the first object 10. Accordingly, the seat body 11 is rotated after the seat body 11 is passed and disposed on the first object 10 with the assembling part 111, so that the assembling part 111 is disposed on the bottom surface of the first object 10 (e.g., the assembling part 111 is abutted against the bottom surface of the first object 10), and the elastic fastening parts 112 are disposed on the surface of the first object 10 (e.g., the elastic fastening parts 112 are abutted against the surface of the first object 10), so that the first object 10 is sandwiched between the assembling part 111 and the elastic fastening parts 112, and thus the seat body 11 is firmly disposed on the first object 10 to facilitate movement operation of the first fastening body 12 and the second fastening body 13.

In one embodiment of the present disclosure, the seat body 11 has an accommodating area 113, the first fastening body 12 is movably provided in the accommodating area 113. Thus, when the first fastening body 12 moves laterally on the seat body 11, the accommodating area 113 may be used as a movement space to achieve the effect of smooth movement, so as to facilitate the action of locking or unlocking.

In one embodiment of the present disclosure, the first fastening body 12 (or the seat body 11) is provided with a sliding part 121, the sliding part 121 is disposed in the seat body 11 (or the first fastening body 12) with a bolt part 122, so that the first fastening body 12 is movably provided in the seat body 11; when the first fastening body 12 moves laterally on the seat body 11, the accommodating area 113 may be used as a movement space, and the sliding part 121 is used to cooperate with the bolt part 122 as a guide and stroke restriction at moving to achieve the effect of smooth movement, so as to facilitate the action of locking or unlocking.

In one embodiment of the present disclosure, a top of one end of the seat body 11 has a first setting part 114, a bottom of one end of the first fastening body 12 has a first fixing part 123, the first setting part 114 corresponds to the first fixing part 123, so that the first fixing part 123 cooperates with the first setting part 114 for fastening and unfastening to couple with or separate from the second object 20; also, the first fixing part 123 has a first limiting flange 124, the second object 20 has a recess part 201, the recess part 201 of the second object 20 is fitted into the first limiting flange 124.

Based on the above embodiment, when used, the fastening device 1 may be combined on the first object 10, and then an inner edge of the recess part 201 of the second object 20 is directly pressed down at the first fixing part 123 of one end of the first fastening body 12 to make the first fastening body 12 move laterally, so that a bottom of the first fixing part 123 of the first fastening body 12 cooperates with a top of the first setting part 114 of the seat body 11 to fasten to the second object 20, and the recess part 201 of the second object 20 is fitted into the first limiting flange 124, thereby locking the first fastening body 12 on the second object 20, and thus the first fastening body 12 and the second object 20 are coupled together (as shown in FIGS. 5 and 6); the third object 30 is then placed on a surface of one end of the first fastening body 12, and the second fastening body 13 is rotationally moved, so that a bottom of one end of the second fastening body 13 cooperates with a top of one end of the first fastening body 12 to fasten to the third object 30, thereby locking the second fastening body 13 on the third object 30, and thus the second fastening body 13 and the third object 30 are coupled together (as shown in FIGS. 7 to 12).

When the second object 20 and the third object 30 are to be separated, the first fastening body 12 moves laterally toward a direction away from the second object 20 and the third object 30, so that the first fastening body 12 links the second fastening body 13, and thus the first fixing part 123 of one end of the first fastening body 12 is separated from the second object 20, and the second fastening body 13 is simultaneously separated from the third object 30 (as shown in FIGS. 13 to 14); in addition, the second fastening body 13 may also be rotated, so that the bottom of one end of the second fastening body 13 leaves the third object 30, and then the movement of the first fastening body 12 is performed. Accordingly, the seat body 11 may be combined with the first object 10, and the first fastening body 12 is used to cooperate with the second fastening body 13 to perform fastening and unfastening, so that the first fastening body 12 and the second fastening body 13 are coupled together or separated from the second object 20 and the third object 30, so as to couple together and separate the two objects, and achieve the effect of coupling together and separating repeatedly and quickly.

In one embodiment of the present disclosure, the first fastening body 12 has an operating part 125, the operating part 125 may control the first fastening body 12 to move on the seat body 11, the operating part 125 may control the first fastening body 12 to move laterally on the seat body 11. Accordingly, when moving the first fastening body 12, force can be applied to the operating part 125 for control, so as to facilitate controlling the first fastening body 12 to cooperate with the seat body 11 for fastening and unfastening, and easy to link the second fastening body 13 to couple together and separate the two objects, and achieve the effect of coupling together and separating repeatedly and quickly.

In one embodiment of the present disclosure, the first fastening body 12 and the seat body 11 therebetween have a first elastic element 14, one end of the first elastic element 14 abuts against the seat body 11, the other end of the first elastic element 14 abuts against the first fastening body 12; in an embodiment of the present disclosure, the first fastening body 12 has a blocking part 126, one end of the first elastic element 14 abuts against the seat body 11, the other end of the first elastic element 14 abuts against the blocking part 126, and the first elastic element 14 can make the first fastening body 12 normally located in a locking position or normally located in an unlocking position.

Based on the above embodiment, when used, the fastening device 1 may be combined on the first object 10, and then an inner edge of the recess part 201 of the second object 20 is directly pressed down at the first fixing part 123 of one end of the first fastening body 12, and the first elastic element 14 is compressed to make the first fastening body 12 move laterally, and then the first fastening body 12 is pushed to restore by the release of elasticity force of the first elastic element 14, so that a bottom of the first fixing part 123 of the first fastening body 12 cooperates with a top of the first setting part 114 of the seat body 11 to fasten to the second object 20, and the recess part 201 of the second object 20 is fitted into the first limiting flange 124, thereby locking the first fastening body 12 on the second object 20, and thus the first fastening body 12 and the second object 20 are coupled together (as shown in FIGS. 5 and 6); the third object 30 is then placed on a surface of one end of the first fastening body 12, and the second fastening body 13 is rotationally moved, so that a bottom of one end of the second fastening body 13 cooperates with a top of one end of the first fastening body 12 to fasten to the third object 30, thereby locking the second fastening body 13 on the third object 30, and thus the second fastening body 13 and the third object 30 are coupled together (as shown in FIGS. 7 to 12).

When the second object 20 and the third object 30 are to be separated, force can be applied to the operating part 125 to laterally move the first fastening body 12 toward a direction away from the second object 20 and the third object 30, and compress the first elastic element 14, so that the first fastening body 12 links the second fastening body 13, and thus the first fixing part 123 of one end of the first fastening body 12 is separated from the second object 20, and the second fastening body 13 is simultaneously separated from the third object 30 (as shown in FIGS. 13 to 14), and elasticity force of the first elastic element 14 is released to push the first fastening body 12 to restore; in addition, the second fastening body 13 may also be rotated, so that the bottom of one end of the second fastening body 13 leaves the third object 30, and then the movement of the first fastening body 12 is performed. Accordingly, the seat body 11 may be combined with the first object 10, and the first fastening body 12 is used to cooperate with the second fastening body 13 to perform fastening and unfastening, so that the first fastening body 12 and the second fastening body 13 are coupled together or separated from the second object 20 and the third object 30, so as to couple together and separate the two objects, and achieve the effect of coupling together and separating repeatedly and quickly.

In one embodiment of the present disclosure, the second fastening body 13 is movably provided in the first fastening body 12 with a shaft part 131, and the shaft part 131 is pressured by external force to combine the first fastening body 12 by expanding connection. Thus, the second fastening body 13 may be pulled upward and rotationally moved on the first fastening body 12 by the shaft part 131, so that a bottom of one end of the second fastening body 13 cooperates with a top of one end of the first fastening body 12 to fasten to the third object 30, or the bottom of one end of the second fastening body 13 leaves the third object 30.

In one embodiment of the present disclosure, a bottom of the second fastening body 13 has a positioning part 132, a top of the first fastening body 12 has a first restriction part 127 and a second restriction part 128, when the positioning part 132 is combined in the first restriction part 127, the second fastening body 13 is located in an unfastening position, when the positioning part 132 is combined in the second restriction part 128, the second fastening body 13 is located in a fastening position.

Based on the above embodiment, when used, the fastening device 1 may be combined on the first object 10, and then an inner edge of the recess part 201 of the second object 20 is directly pressed down at the first fixing part 123 of one end of the first fastening body 12, and the first elastic element 14 is compressed to make the first fastening body 12 move laterally, and then the first fastening body 12 is pushed to restore by the release of elasticity force of the first elastic element 14, so that a bottom of the first fixing part 123 of the first fastening body 12 cooperates with a top of the first setting part 114 of the seat body 11 to fasten to the second object 20, and the recess part 201 of the second object 20 is fitted into the first limiting flange 124, thereby locking the first fastening body 12 on the second object 20, and thus the first fastening body 12 and the second object 20 are coupled together (as shown in FIGS. 5 and 6); the third object 30 is then placed on a surface of one end of the first fastening body 12 (at this time, the positioning part 132 is combined in the first restriction part 127, so that the second fastening body 13 is located in the unfastening position), and then the second fastening body 13 is first pulled upward with the cooperation of the shaft part 131, and the second fastening body 13 is rotationally moved to make the positioning part 132 combine in the second restriction part 128, so that a bottom of one end of the second fastening body 13 cooperates with a top of one end of the first fastening body 12 to fasten to the third object 30, thereby locking the second fastening body 13 on the third object 30, and thus the second fastening body 13 and the third object 30 are coupled together (as shown in FIGS. 7 to 12).

When the second object 20 and the third object 30 are to be separated, the second fastening body 13 is first pulled upward with the cooperation of the shaft part 131, and then the second fastening body 13 is rotationally moved to make the bottom of one end of the second fastening body 13 leave the third object 30, and make the positioning part 132 combine in the first restriction part 127, and then force can be applied to the operating part 125 to laterally move the first fastening body 12 toward a direction away from the second object 20 and the third object 30, and compress the first elastic element 14, so that the first fastening body 12 links the second fastening body 13, and thus the first fixing part 123 of one end of the first fastening body 12 is separated from the second object 20, and the second fastening body 13 is simultaneously separated from the third object 30 (as shown in FIGS. 13 to 14), and elasticity force of the first elastic element 14 is released to push the first fastening body 12 to restore; in addition, the second fastening body 13 can also be first pulled upward with the cooperation of the shaft part 131, and then the second fastening body 13 is rotated, so that the bottom of one end of the second fastening body 13 leaves the third object 30, and the positioning part 132 is combined in the first restriction part 127, and then the movement of the first fastening body 12 is performed. Accordingly, the seat body 11 may be combined with the first object 10, and the first fastening body 12 is used to cooperate with the second fastening body 13 to perform fastening and unfastening, so that the first fastening body 12 and the second fastening body 13 are coupled together or separated from the second object 20 and the third object 30, so as to couple together and separate the two objects, and achieve the effect of coupling together and separating repeatedly and quickly.

In one embodiment of the present disclosure, one end of the second fastening body 13 has a second fixing part 133, the first fastening body 12 has a second setting part 129, the third object 30 is disposed on the second setting part 129, and then the second fastening body 13 is rotated, so that the second fixing part 133 couples with the third object 30.

In one embodiment of the present disclosure, one end of the second fastening body 13 has a second fixing part 133, the other end of the second fastening body 13 has a give-way part 134, the second fastening body 13 is rotated after the third body 30 passes through the give-way part 134, so that the second fixing part 133 couples with the third object 30; in an embodiment of the present disclosure, the first fastening body 12 has a second setting part 129, the third object 30 is disposed on the second setting part 129 after passing through the give-way part 134, and then the second fastening body 13 is rotated, so that the second fixing part 133 couples with the third object 30. In addition, in one embodiment of the present disclosure, the second setting part 129 has a second limiting flange 1291, the third object 30 has a recess part 301, the recess part 301 of the third object 30 is fitted into the second limiting flange 1291.

Based on the above embodiment, when used, the fastening device 1 may be combined on the first object 10, and then an inner edge of the recess part 201 of the second object 20 is directly pressed down at the first fixing part 123 of one end of the first fastening body 12, and the first elastic element 14 is compressed to make the first fastening body 12 move laterally, and then the first fastening body 12 is pushed to restore by the release of elasticity force of the first elastic element 14, so that a bottom of the first fixing part 123 of the first fastening body 12 cooperates with a top of the first setting part 114 of the seat body 11 to fasten to the second object 20, and the recess part 201 of the second object 20 is fitted into the first limiting flange 124, thereby locking the first fastening body 12 on the second object 20, and thus the first fastening body 12 and the second object 20 are coupled together (as shown in FIGS. 5 and 6); the recess part 301 of the third object 30 is then disposed on the second setting part 129 after passing through the give-way part 134, and the recess part 301 is fitted into the second limiting flange 1291 (at this time, the positioning part 132 is combined in the first restriction part 127, so that the second fastening body 13 is located in the unfastening position), and then the second fastening body 13 is first pulled upward with the cooperation of the shaft part 131, and the second fastening body 13 is rotationally moved to make the positioning part 132 combine in the second restriction part 128, so that the second fixing part 133 of one end of the second fastening body 13 cooperates with the second setting part 129 of the first fastening body 12 to fasten to the third object 30, thereby locking the second fastening body 13 on the third object 30, and thus the second fastening body 13 and the third object 30 are coupled together (as shown in FIGS. 7 to 12).

When the second object 20 and the third object 30 are to be separated, force can be applied to the operating part 125 to laterally move the first fastening body 12 toward a direction away from the second object 20 and the third object 30, and compress the first elastic element 14, so that the first fastening body 12 links the second fastening body 13, and thus the first fixing part 123 of one end of the first fastening body 12 is separated from the second object 20, and the second fixing part 133 of the second fastening body 13 is simultaneously separated from the third object 30, so that the recess part 301 is fitted into the second limiting flange 1291 (as shown in FIGS. 13 to 14), and elasticity force of the first elastic element 14 is released to push the first fastening body 12 to restore; in addition, the second fastening body 13 can also be first pulled upward with the cooperation of the shaft part 131 to make the second fixing part 133 move away the third object 30, and then the second fastening body 13 is rotated, so that the bottom of one end of the second fastening body 13 leaves the third object 30, and the positioning part 132 is combined in the first restriction part 127, and then the movement of the first fastening body 12 is performed. Accordingly, the seat body 11 may be combined with the first object 10, and the first fastening body 12 is used to cooperate with the second fastening body 13 to perform fastening and unfastening, so that the first fastening body 12 and the second fastening body 13 are coupled together or separated from the second object 20 and the third object 30, so as to couple together and separate the two objects, and achieve the effect of coupling together and separating repeatedly and quickly.

In one embodiment of the present disclosure, the second fastening body 13 is used to apply a coupling force of normal elastic downward pressure to press against the third object 30, so that the first fastening body 12 and the second fastening body 13 are coupled together or separated from the second object 20 and the third object 30, so as to couple together and separate the two objects, and achieve the effect of coupling together and separating repeatedly and quickly.

In one embodiment of the present disclosure, the shaft part 131 is provided with a second elastic element 15, one end of the second elastic element 15 abuts against the first fastening body 12, the other end of the second elastic element 15 abuts against one end of the shaft part 131, the second elastic element 15 can make the second fastening body 13 normally located at a top of the first fastening body 12. Accordingly, when the second fastening body 13 pulls upward with the cooperation of the shaft part 131, the second elastic element 15 is immediately compressed, and after the second fastening body 13 completes the action of rotational movement, the shaft part 131 may be pushed by the release of the elasticity of the second elastic element 15, so that the shaft part 131 drives the second fastening body 13 to be normally located at the top of the first fastening body 12, so as to facilitate the reoperation of the second fastening body 13.

In one embodiment of the present disclosure, the second object 20 or the third object 30 may be a printed circuit board, PCB board, computer carrier board, heat dissipating sheet, radiator, memory, M.2 card, metallic piece, hard disk, chip, semiconductor, heating element, heat dissipating element, plastic piece or non-metallic piece. Accordingly, the present disclosure can further meet the requirement of practical application.

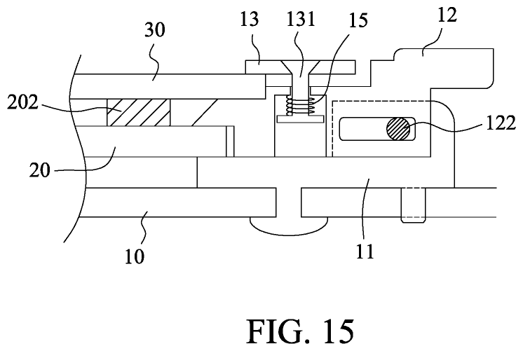

In one embodiment of the present disclosure, the second elastic element 15 may enable the second fastening body 13 to apply a coupling force of normal elastic downward pressure to press against the third object 30 by the spring force of the second elastic element 15 (as shown in FIG. 15). Accordingly, the present disclosure can further meet the requirement of practical application.

In one embodiment of the present disclosure, the second object 20 may be a heating element, the third object 30 may be a heat dissipation element, wherein the third object 30 is used to dissipate heat for the second object 20; in the present embodiment, the third object 30 is used to be pressed down by the spring force of the second elastic element 15 on the second object 20 or the chip 202 of the second object 20, so that the third object 30 dissipates heat from the chip 202 on the second object 20 (as shown in FIGS. 13 and 15). Accordingly, the present disclosure can further meet the requirement of practical application.

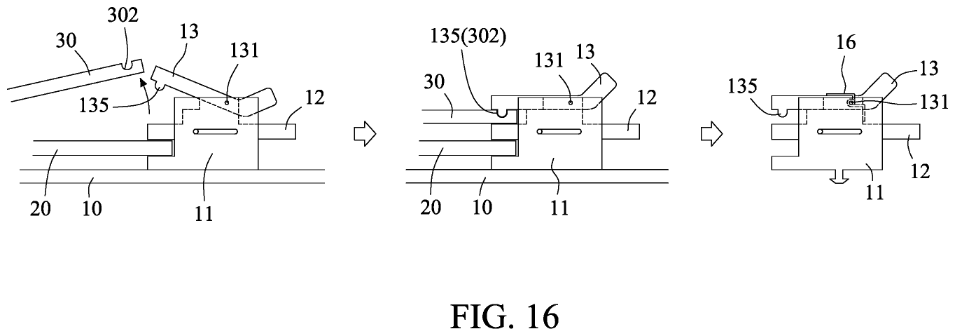

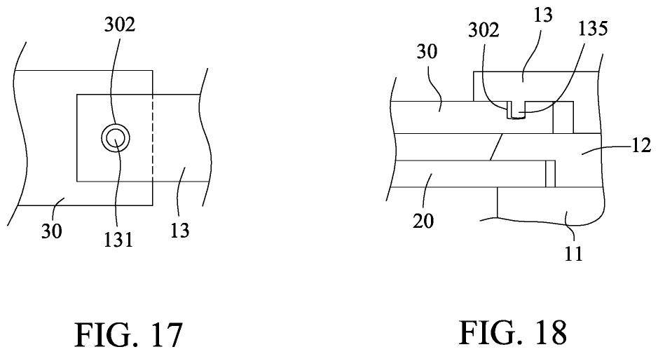

Referring to FIGS. 16 and 18, as shown in the drawings, in an embodiment of the present disclosure, the embodiment is different from the above embodiment in that the first fastening body 12 is movably provided in the seat body 11, so that the first fastening body 12 moves to couple with or separate from a second object 20, and the second fastening body 13 is movably provided in the first fastening body 12, so that the second fastening body 13 moves to couple with or separate from a third object 30.

In one embodiment of the present disclosure, the second fastening body 13 is movably provided in the first fastening body 12 with a shaft part 131, and has a second elastic element 15, one end of the second elastic element 15 abuts against the first fastening body 12, the other end of the second elastic element 15 abuts against the second fastening body 13, the second elastic element 15 can make the second fastening body 13 normally located at a top of the first fastening body 12, and the second elastic element 15 may enable the second fastening body 13 to apply a coupling force of normal elastic downward pressure to press against the third object 30.

In one embodiment of the present disclosure, the second fastening body 13 is pushed and abutted by the second elastic element 15 for rotationally elastic movement.

In one embodiment of the present disclosure, the second fastening body 13 has a fixing part 135, the third object 30 has a corresponding fixing part 302, the fixing part 135 and the corresponding fixing part 302 are engaged with each other for fixing or anti-rotation or abutting against or fastening or applying pressure or pressing downward.

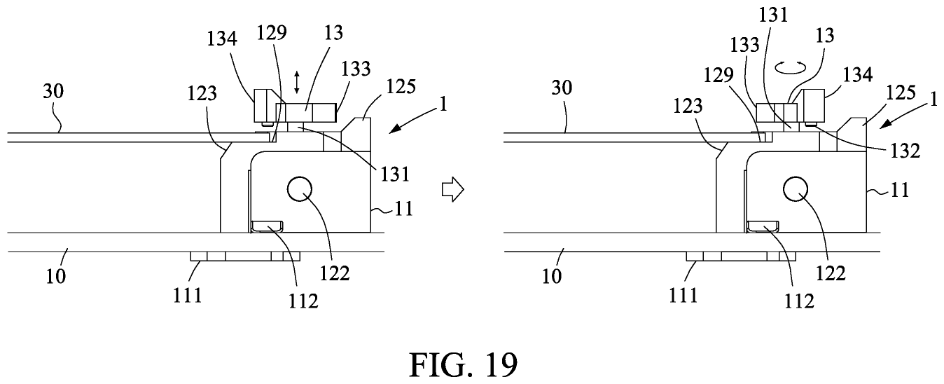

Referring to FIG. 19, as shown in the drawing, in an embodiment of the present disclosure, the embodiment is different from the above embodiment in that the fastening device 1 comprises a seat body 11 and a second fastening body 13, without the need to provide the first fastening body 12. The seat body 11 may be provided on a first object 10; the second fastening body 13 is movably provided in the seat body 11, so that the second fastening body 13 rotationally moves to couple with or separate from a third object 30.

When used, the fastening device 1 may be combined on the first object 10, the third object 30 is then placed on a surface of one end of the seat body 11, and the second fastening body 13 is rotationally moved, so that a bottom of one end of the second fastening body 13 fastens to the third object 30, thereby locking the second fastening body 13 on the third object 30, and thus the second fastening body 13 and the third object 30 are coupled together.

When the third object 30 is to be separated, the second fastening body 13 may be rotated, so that the bottom of one end of the second fastening body 13 leaves the third object 30. Accordingly, the seat body 11 may be combined with the first object 10, and the second fastening body 13 is used to perform fastening and unfastening, so that the second fastening body 13 is coupled together or separated from the third object 30, so as to couple together and separate the two objects, and achieve the effect of coupling together and separating repeatedly and quickly.

While the present invention has been described by means of specific embodiments, numerous modifications and variations could be made thereto by those skilled in the art without departing from the scope and spirit of the present invention set forth in the claims.

What is claimed is:

1. A fastening device, comprising:
a seat body, disposed on a first object;
a first fastening body, movably provided in the seat body, so that the first fastening body moves to couple with or separate from a second object; and
a second fastening body, movably provided in the first fastening body, so that the second fastening body moves to couple with or separate from a third object.

2. The fastening device according to claim 1, wherein the first fastening body laterally moves to couple with or separate from the second object, the second fastening body rotationally moves to couple with or separate from the third object.

3. A fastening device, comprising:
a seat body, disposed on a first object; and
a second fastening body, movably provided in the seat body, so that the second fastening body rotationally moves to couple with or separate from a third object.

4. The fastening device according to claim 1, wherein the seat body has at least one assembling part or at least one elastic fastening part, or the assembling part is provided for the seat body to be disposed on the first object, or the elastic fastening parts abut against the first object.

5. The fastening device according to claim 3, wherein the seat body has at least one assembling part or at least one elastic fastening part, or the assembling part is provided for the seat body to be disposed on the first object, or the elastic fastening parts abut against the first object.

6. The fastening device according to claim 1, wherein the seat body has an accommodating area, the first fastening body is movably provided in the accommodating area.

7. The fastening device according to claim 1, wherein the first fastening body or the seat body is provided with a sliding part, the sliding part is disposed in the seat body or the first fastening body with a bolt part, so that the first fastening body is movably provided in the seat body.

8. The fastening device according to claim 1, wherein the seat body has a first setting part, the first fastening body has a first fixing part, the first setting part corresponds to the first fixing part, so that the first fixing part cooperates with the first setting part for fastening and unfastening to couple with or separate from the second object, or the first fixing part has a first limiting flange, or the second object has a recess part, or the recess part of the second object is fitted into the first limiting flange.

9. The fastening device according to claim 1, wherein the first fastening body and the seat body therebetween have a first elastic element, the first fastening body has a blocking part, one end of the first elastic element abuts against the seat body, the other end of the first elastic element abuts against the blocking part, and the first elastic element can make the first fastening body normally located in a locking position or normally located in an unlocking position.

10. The fastening device according to claim 1, wherein the second fastening body is movably provided in the first fastening body with a shaft part, or the shaft part is pressured by external force to combine the first fastening body by expanding connection.

11. The fastening device according to claim 1, wherein the second fastening body has a positioning part, the first fastening body has a first restriction part or a second restriction part, when the positioning part is combined in the first restriction part, the second fastening body is located in an unfastening position or fastening position, or when the positioning part is combined in the second restriction part, the second fastening body is located in a fastening position or unfastening position.

12. The fastening device according to claim 1, wherein one end of the second fastening body has a second fixing part, the other end of the second fastening body has a give-way part, the second fastening body is rotated after the third body passes through the give-way part, so that the second fixing part couples with the third object.

13. The fastening device according to claim 3, wherein one end of the second fastening body has a second fixing part, the other end of the second fastening body has a give-way part, the second fastening body is rotated after the third body passes through the give-way part, so that the second fixing part couples with the third object.

14. The fastening device according to claim 1, wherein one end of the second fastening body has a second fixing part, the other end of the second fastening body has a give-way part, the first fastening body has a second setting part, the third object is disposed on the second setting part after passing through the give-way part, and then the second fastening body is rotated, so that the second fixing part couples with the third object, or the second setting part has a second limiting flange, or the third object has a recess part, or the recess part of the third object is fitted into the second limiting flange.

15. The fastening device according to claim 1, wherein the second fastening body is movably provided in the first fastening body with a shaft part, the shaft part is provided with a second elastic element, one end of the second elastic element abuts against the first fastening body, the other end of the second elastic element abuts against one end of the shaft part, the second elastic element can make the second fastening body normally located at a top of the first fastening body.

16. The fastening device according to claim 1, wherein the second fastening body is movably provided in the first fastening body with a shaft part, the shaft part is provided with a second elastic element, one end of the second elastic element abuts against the first fastening body, the other end of the second elastic element abuts against one end of the shaft part, the second elastic element enables the second fastening body to apply a coupling force of normal elastic downward pressure to press against the third object.

17. The fastening device according to claim 1, wherein the second fastening body is used to apply a coupling force of normal elastic downward pressure to press against the third object.

18. The fastening device according to claim 3, wherein the second fastening body is used to apply a coupling force of normal elastic downward pressure to press against the third object.

19. The fastening device according to claim 1, wherein the second fastening body is movably provided in the first fastening body with a shaft part, and has a second elastic element, one end of the second elastic element abuts against the first fastening body, the other end of the second elastic element abuts against the second fastening body, the second elastic element can make the second fastening body normally located at a top of the first fastening body.

20. The fastening device according to claim 1, wherein the second fastening body is movably provided in the first fastening body with a shaft part, and has a second elastic element, one end of the second elastic element abuts against the first fastening body, the other end of the second elastic element abuts against the second fastening body, the second elastic element enables the second fastening body to apply a coupling force of normal elastic downward pressure to press against the third object.

21. The fastening device according to claim 1, wherein the second fastening body has a fixing part, the third object has a corresponding fixing part, the fixing part and the corresponding fixing part are engaged with each other for fixing or anti-rotation or abutting against or fastening or applying pressure or pressing downward.

22. The fastening device according to claim 3, wherein the second fastening body has a fixing part, the third object has a corresponding fixing part, the fixing part and the corresponding fixing part are engaged with each other for fixing or anti-rotation or abutting against or fastening or applying pressure or pressing downward.
